(19) United States
(12) Patent Application Publication
(10) Pub. No.: US 2007/0182432 A1
(43) Pub. Date: Aug. 9, 2007

(54) Insert with support for semiconductor package

(75) Inventors: Hyeck-Jin Jeong, Cheonan-si (KR); Seon-Ju Oh, Cheonan-si (KR); Seok-Young Yoon, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/488,597

(22) Filed: Jul. 19, 2006

(30) Foreign Application Priority Data
Jan. 26, 2006 (KR) 2006-8303

(51) Int. Cl. G01R 31/02

(52) U.S. Cl. 324/755

(57) ABSTRACT

An insert for loading a semiconductor package having external connection terminals may have a support plate. The support plate may have an upper surface with first contact pads and a lower surface with second contact pads. The first contact pads may be electrically connected to the external connection terminals of the semiconductor package and the second contact pads may be electrically connected to test connection terminals of a test socket.

### PRIORITY STATEMENT

This U.S. non-provisional application claims benefit of priority under 35 U.S.C.§119 from Korean Patent Application No. 2006-8303, filed on Jan. 26, 2006, the entire contents of which are incorporated herein by reference.

### BACKGROUND

### Field of the Invention

Example embodiments of the present invention relate generally to an insert for loading a semiconductor package.

### Description of the Related Art

During semiconductor package manufacturing processes, semiconductor packages may undergo various tests in terms of electrical and/or functional properties to ensure reliability. In a semiconductor package test process, a handler serving as a semiconductor package handling apparatus may be used to transport manufactured semiconductor packages to a testing apparatus and/or to sort the tested semiconductor packages.

The handler may convey a plurality of semiconductor packages to the testing apparatus and/or perform a test operation by electrically contacting each semiconductor package through a test socket to a test head. The handler may remove each tested semiconductor package from the test head and may sort the tested semiconductor package according to test results thereof.

For example, the handler may convey a test tray to the testing apparatus to proceed with the package test process. The test tray may include a plurality of inserts. Each insert may hold a semiconductor package, for example a ball grid array (BGA) package. Of course the insert may accommodate various other types of semiconductor packages.

A conventional insert 1 for holding a semiconductor package 2 is shown in FIG. 1. Here, the insert 1 may include an insert body 7 that may have a pocket 4 into which the semiconductor package 2 may be inserted. A support 5 may be provided for supporting the semiconductor package 2 in the pocket 4. Latches 6 may be provided for securing the semiconductor package 2 in the pocket 4.

When loading the semiconductor package 2 in the insert 1, the latches 6 may be retracted into the insert body 7. When the semiconductor package 2 is provided on the support 5, the latches 6 may be advanced to secure the semiconductor package 2 in place.

The support 5 may support the semiconductor package 2 such that a supporting portion of the support 5 may contact with a peripheral area of the semiconductor package 2. Conductive bumps 3 of the semiconductor package 2, which may be exposed from the insert 1, may contact with pogo pins (not shown), for example, of a test socket (not shown) to test the semiconductor package 2.

To stably support the semiconductor package 2, a supporting portion of the support 5 may contact with a space (A) between the outermost conductive bump 3 and the edge of the semiconductor package 2. Conventionally, the space (A) may be 0.8 mm.

The size of the semiconductor package may be reduced and/or the number of external connection terminals may be increased. As a result, the space between the outermost conductive bump and the edge of the semiconductor package may be reduced to, for example 0.2 mm or less. Consider FIG. 2, for example.

Referring to FIG. 2, a semiconductor package 20 may be loaded in an insert 1. The space (B) between the outermost conductive bump 30 and the edge of the semiconductor package 20 may be 0.2 mm or less. A portion of conductive bumps 30 may not be exposed from the insert 1, thus obstructing an electrical connection to a test socket.

As one possible solution, the supporting portion of the support 5 may be reduced in conformity with the space (B). At the same time, however, the supporting portion of the support 5 should have a sufficient size to stably support the semiconductor package 20. Thus, there may be a limitation in reducing the size of the supporting portion of the support 5. For example, if the space (B) is 0.2 mm, the supporting portion of the support 5 may have size of 0.2 mm or less. However, an excessively reduced size of the supporting portion of the support 5 may result in an unstable support of the semiconductor package 20.

### SUMMARY

According to an example, non-limiting embodiment, an insert may be provided for loading a semiconductor package that may have external connection terminals. The insert may include a body having a pocket that may be configured to receive the semiconductor package. A support plate may have an upper surface and a lower surface. The support plate may be connected to the body and configured to support the semiconductor package. The upper surface of the support plate may contact the external connection terminals of the semiconductor package. The support plate may electrically connect the external connection terminals to test connection terminals of a test socket.

According to another example, non-limiting embodiment, an insert may be provided for loading a semiconductor package that may have external connection terminals. The insert may include a body having a pocket that may be configured to receive the semiconductor package. A support plate may extend entirely across the pocket. The support plate may have an upper surface facing the pocket and a lower surface facing away from the pocket. The support plate may be configured to electrically connect the external connection terminals to test connection terminals of a test socket.

### BRIEF DESCRIPTION OF THE DRAWINGS

Example, non-limiting embodiments of the present invention will be readily understood with reference to the following detailed description thereof provided in conjunction with the accompanying drawings, wherein like reference numerals designate like structural elements.

FIG. 1 is a cross sectional view of a conventional insert for loading a semiconductor package.

FIG. 2 is a cross sectional view illustrating a fault of a conventional insert for loading a semiconductor package.

FIG. 3A is a cross sectional view of an insert for loading a semiconductor package according to an example, non-limiting embodiment of the present invention.

FIG. 3B is a partially enlarged view of an insert for loading a semiconductor package according to an example, non-limiting embodiment of the present invention.

FIG. 4 is a partially enlarged view of an insert for loading a semiconductor package according to another example, non-limiting embodiment of the present invention.

FIG. 5A is a cross sectional view of an insert for loading a semiconductor package according to another example, non-limiting embodiment of the present invention.

FIG. 5B is a partially enlarged view of an insert for loading a semiconductor package according to another example, non-limiting embodiment of the present invention.

### DESCRIPTION OF EXAMPLE, NON-LIMITING EMBODIMENTS

Example, non-limiting embodiments of the present invention will be described with reference to the accompanying drawings. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. The principles and features of this invention may be employed in varied and numerous embodiments without departing from the scope of the invention.

Well-known structures and processes are not described or illustrated in detail to avoid obscuring the present invention.

An element is considered as being mounted (or provided) “on” another element when mounted or provided) either directly on the referenced element or mounted (or provided) on other elements overlaying the referenced element. Throughout this disclosure, spatial terms such as “upper,” “lower,” “above” and “below” (for example) are used for convenience in describing various elements or portions or regions of the elements as shown in the figures. These terms do not, however, require that the structure be maintained in any particular orientation.

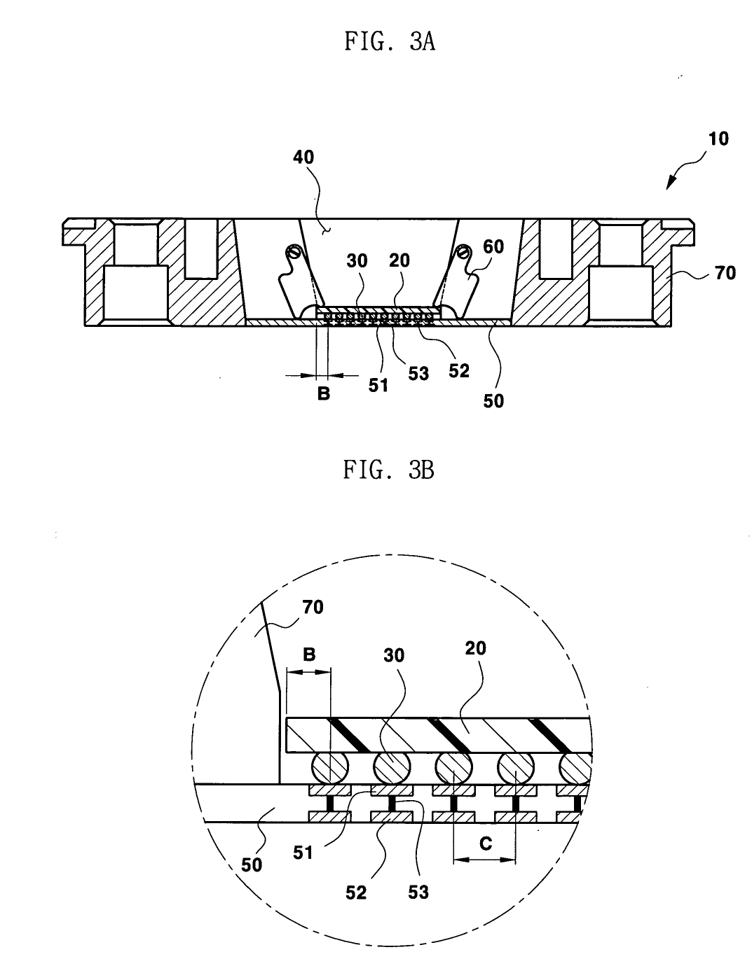

An example embodiment of the present invention will be described with respect to FIGS. 3A and 3B. FIG. 3A is a cross sectional view of an insert 10 for loading a semiconductor package 20. FIG. 3B is a partially enlarged view of the insert 10.

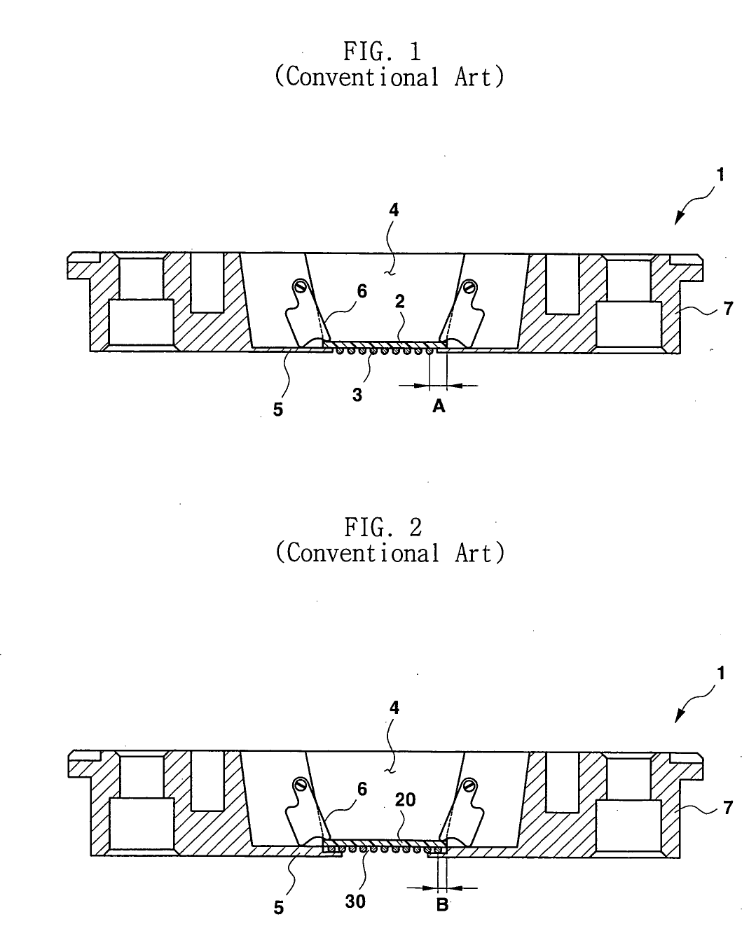

Components of the insert 10, for example the insert body 70, the pocket 40 and/or latches 60, may have the same structure as those of the conventional insert 1 (depicted in FIGS. 1 and 2), and therefore a detailed description of the same is omitted.

Referring to FIG. 3A, the insert 10 may include a support plate 50 having an upper surface and a lower surface. First contact pads 51 may be provided on the upper surface of the support plate 50 and second contact pads 52 may be provided on the lower surface of the support plate 50.

The first contact pads 51 may be arranged corresponding to conductive bumps 30 of the semiconductor package 20. The first contact pads 51 may be electrically connected to the conductive bumps 30. The pitch of the first contact pads 51 may be the same as the pitch (C) of the conductive bumps 30.

The second contact pads 52 may be electrically connected to test connection terminals of a test socket (not shown). The second contact pads 52 may be electrically connected to the first contact pads 51 through via holes 53. The pitch of the second contact pads 52 may be the same as the pitch of the first contact pads 51. Although not shown, the pitch of the test connection terminals of the test socket may be the same as the pitch of the second contact pads 52. The via holes 53 may be filled with conductive materials.

To conduct testing on the semiconductor package 20, the first contact pads 51 may be electrically connected to the second contact pads 52 and the second contact pad 52 may be electrically connected to the test connection terminals of the test socket.

The support plate 50 and the insert body 70 may be of an integral, one-piece construction, or provided as separate and distinct components. For example, when provided as separate and distinct components, the support plate 50 may be connected to the insert body 70 using physical and/or chemical connection mechanisms.

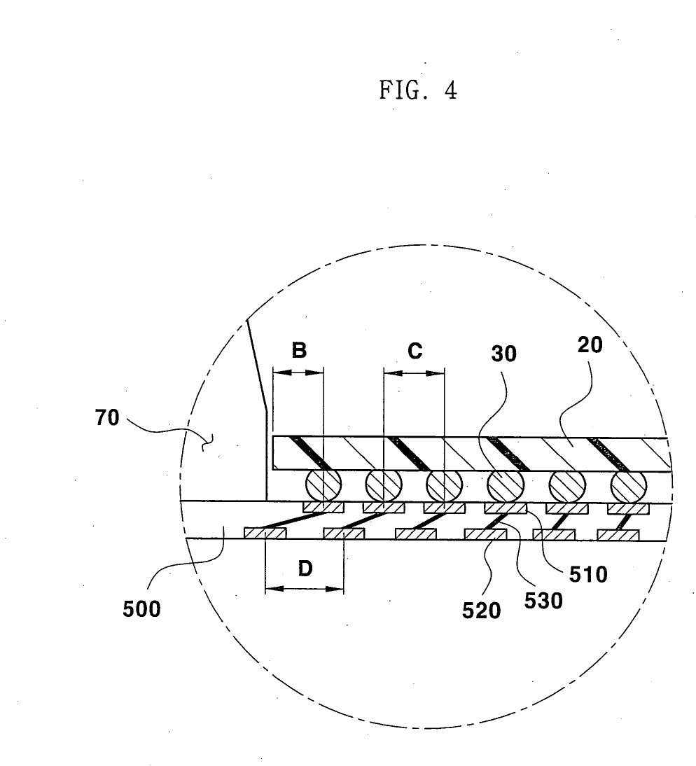

FIG. 4 is a partially enlarged view of an insert for loading a semiconductor package according to another example, non-limiting embodiment of the present invention.

The insert of this example embodiment may have the same structure as the insert 10 of the first embodiment, except for the support plate 500.

The support plate 500 may have first and second contact pads 510 and 520. The pitch (C) of the first contact pads 510 may be different than the pitch (D) of the second contact pads 520.

When a semiconductor package (e.g., a BGA package) is tested, the semiconductor package may be influenced by a clearance factor. That is, lateral clearance may be created between the semiconductor package, the insert, and a test socket. When the semiconductor package is loaded in the insert and/or the insert comes in contact with a test socket, the lateral clearance may be generated. Consider a scenario in which the pitch of the first and the second contact pads may be 0.3 mm and the lateral clearance may be about 0.1 mm. Here, semiconductor packages having a small pitch between conductive bumps (e.g., fine pitch BGA packages) may experience poor electrical connection of the conductive bumps to the test connection terminal of the test socket. Further, it may be difficult to produce a test socket having test connection terminals at a pitch of 0.3 mm.

In the insert of this example embodiment, the pitch (D) of the second contact pad 520 may be greater than the pitch (C) of the first contact pad 510. By way of example only, the pitch (D) may be greater than the pitch (C) by 0.5 mm. This may reduce the likelihood for poor electrical connection caused by lateral clearance that may occur between the components of the insert, and facilitate a process for producing a test socket.

Via holes 530 that may connect the first contact pad 510 to the second contact pad 520 may be slanted. In alternative embodiments, the via holes may not extend in a straight line fashion. For example, the via holes may meander between the first and the second contact pads.

The difference of the pitch (C) and the pitch (D) may be set according to the type of semiconductor package and/or the pitch between test connection pads of a test socket, for example.

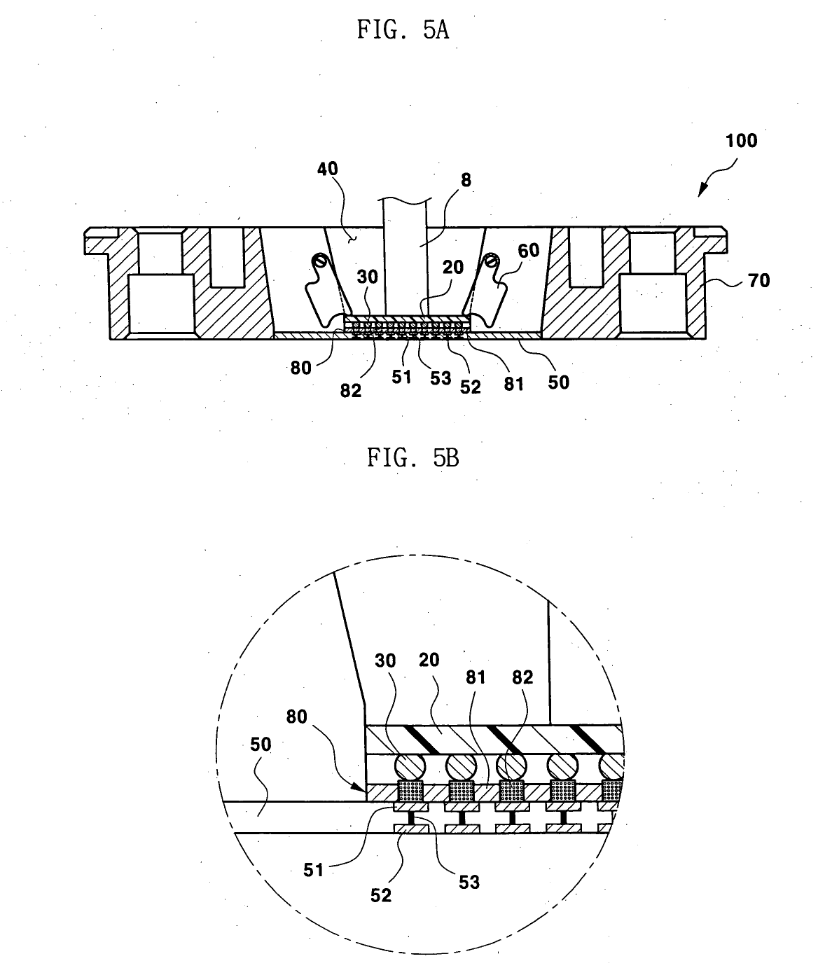

FIG. 5A is a cross sectional view of an insert 100 for loading a semiconductor package according to another example, non-limiting embodiment of the present invention. FIG. 5B is a partially enlarged view of the insert 100.

Referring to FIG. 5A, the insert 100 may have an auxiliary sheet 80. The auxiliary sheet 80 may be provided on an upper surface of a support plate 50. The auxiliary sheet 80 may include a dielectric sheet 81 and contact terminals 82 that may be provided in the dielectric sheet 81.

The dielectric sheet 81 may be fabricated from a dielectric resin film and/or dielectric materials having elasticity, for example rubber. The contact terminals 82 may be fabricated from pressure conductive rubber (PCR) having elasticity. Conductive particles may be included in the PCR. When external pressure from a presser device 8 (for example) is applied to the contact terminals 82, the PCR may be compressed and the conductive particles may come into contact with each other. In this way, the contact terminals 82 may provide an electrical connection between the conductive bumps 30 and the first contact pads 51.

In some instances, the height of the conductive bumps 30 and/or the height of the first contact pads 51 may be irregular, which may make it difficult to electrically connect the conductive bumps 30 to the first contact pads 51.

The auxiliary sheet 80 may reduce the likelihood of poor electrical connections between the conductive bumps 30 and the first contact pads 51. For example, pressure from the presser device 8 may compress the contact terminal 82, thereby achieving contact with even a shorter conductive bump 30 with the corresponding first contact pad 51. For this reason, the contact terminals 82 may protrude from the dielectric sheet 81.

The pitch of the contact terminals 82 may be the same as the pitch of the first contact pads 51 and/or the pitch of the conductive bumps 30. The pitch of the second contact pads 52 may be the same as (as shown in FIGS. 5A and 5B) or greater than (as shown in FIG. 4) the pitch of the first contact pads 51.

Example, non-limiting embodiment the present invention provide an insert for loading and/or supporting a semiconductor package that may have a reduced space between the outermost conductive bump and the edge of the semiconductor package. The pitch between conductive bumps of the semiconductor package may be different than the pitch between test connection terminals of a test socket. As compared to conventional techniques and devices, example embodiments of the present invention may improve the electrical connection between the conductive bump and the test connection terminal and a process for manufacturing an insert and/or a test socket may be simplified.

Further, electrical connection faults between the conductive bumps and the first contact pads, which may result from irregular heights of the conductive bumps and/or the first contact pads, may be reduced.

While example, non-limiting embodiments of the invention have been shown and described in this specification, it will be understood by those skilled in the art that various changes and/or modifications of the embodiments are possible without departing from the spirit and scope of the invention as defined by the appended claims.

What is claimed is:

1. An insert for loading a semiconductor package, the semiconductor package having external connection terminals, the insert comprising:
a body having a pocket configured to receive the semiconductor package; and
a support plate having an upper surface and a lower surface, the support plate connected to the body and configured to support the semiconductor package,
the upper surface of the support plate contacting the external connection terminals of the semiconductor package, and
the support plate electrically connecting the external connection terminals to test connection terminals of a test socket.

2. The insert of claim 1, wherein the support plate has first contact pads provided on the upper surface corresponding to the external connection terminals and second contact pads provided on the lower surface corresponding to the test connection terminals.

3. The insert of claim 2, wherein the support plate has via holes electrically connecting the first contact pads to the second contact pads.

4. The insert of claim 2, wherein an elastic auxiliary sheet is provided on the upper surface of the support plate.

5. The insert of claim 4, wherein the elastic auxiliary sheet includes a dielectric sheet fabricated from a dielectric material having elasticity and contact terminals fabricated from conductive materials and provided in the dielectric sheet corresponding to the first contact pads.

6. The insert of claim 5, wherein the pitch of the contact terminals is the same as the pitch of the first contact pads.

7. The insert of claim 5, wherein the dielectric material includes rubber.

8. The insert of claim 5, wherein the contact terminal is fabricated from conductive rubber.

9. The insert of claim 4, wherein the elastic auxiliary sheet includes a dielectric sheet fabricated from a dielectric resin film and contact terminals fabricated from conductive materials having elasticity and provided in the dielectric sheet corresponding to the first contact pads.

10. The insert of claim 2, wherein a pitch of the first contact pads is the same as a pitch of the second contact pads.

11. The insert of claim 2, wherein a pitch of the first contact pads is different than a pitch of the second contact pads.

12. The insert of claim 11, wherein the pitch of the second contact pads is greater than the pitch of the first contact pads.

13. The insert of claim 1, wherein the support plate and the body are of an integral, one-piece construction.

14. The insert of claim 1, wherein the support plate and the body are two separate component parts that are assembled together.

15. The insert of claim 1, wherein the semiconductor package includes a ball grid array (BGA) package.

16. An insert for loading a semiconductor package, the semiconductor package having external connection terminals, the insert comprising:
a body having a pocket configured to receive the semiconductor package; and
a support plate extending entirely across the pocket, the support plate having an upper surface facing the pocket and a lower surface facing away from the pocket,
the support plate configured to electrically connect the external connection terminals to test connection terminals of a test socket.

17. The insert of claim 16, wherein the support plate includes:
first contact pads provided on the upper surface corresponding to the external connection terminals;
second contact pads provided on the lower surface corresponding to the test connection terminals; and
via holes electrically connecting the first contact pads to the second contact pads.

18. The insert of claim 17, wherein the via holes extend along straight lines.

19. The inset of claim 17, wherein the via holes are inclined relative to the support plate.

20. An assembly comprising:
a test socket; and
the insert of claim 17 mounted on the test socket so that the second contact pads are electrically connected to the test socket.
